(19) United States
(12) Patent Application Publication
(10) Pub. No.: US 2016/0329384 A1
(43) Pub. Date: Nov. 10, 2016

(54) ORGANIC LIGHT-EMITTING DIODE DISPLAY PANEL AND DISPLAY DEVICE

(71) Applicant: BOE TECHNOLOGY GROUP CO., LTD., Beijing (CN)

(72) Inventor: Wenjun HOU, Beijing (CN)

(73) Assignee: BOE TECHNOLOGY GROUP CO., LTD., Beijing (CN)

(21) Appl. No.: 14/893,665

(22) PCT Filed: May 21, 2015
(86) PCT No.: PCT/CN2015/079480

§ 371 Date: Nov. 24, 2015

(30) Foreign Application Priority Data
Dec. 26, 2014 (CN) 201410832109.1

(51) Int. Cl. H01L 27/32

(52) U.S. Cl. CPC H01L 27/3216; H01L 27/3218; H01L 27/3213

(57) ABSTRACT

An organic light-emitting diode display panel and a display device are provided, including a plurality of pixel units (1), each pixel unit including at least sub-pixels of three primary colors of red, green and blue made of different organic electroluminescent materials; the pixel unit includes at least three regions, the number of the regions being equal to the number of sub-pixels in the pixel unit, and each of the regions having a same area; the blue sub-pixel is located in at least two regions, and the other sub-pixels of different primary colors are located in different regions, an area of the blue sub-pixel being greater than those of other sub-pixels of a same primary color.

### TECHNICAL FIELD

Embodiments of the present disclosure relate to an organic light-emitting diode display panel and a display device.

### BACKGROUND

With development of a display technology, an organic light-emitting diode (OLED) display device has been widely applied in a display field. A basic structure of the OLED display device includes an anode, a light-emitting layer, and a cathode, and the light-emitting layer is made of an organic electroluminescent material.

The OLED display has a self-luminous characteristic, that is, when a current passes through the light-emitting layer, the organic electroluminescent material will emit light, and different materials can emit light of different colors. But a single display color is clearly unable to meet a pursuit of people for full-color high-quality images, and a color display of the OLED display device may be realized according to a principle of three primary colors. The principle of three primary colors is to generate other colors by adjusting proportion of three colors of red, green and blue.

### SUMMARY

Embodiments of the disclosure provide an organic light-emitting diode display panel and a display device; as compared with the prior art, a pixel arrangement mode adopted by the organic light-emitting diode display panel in the embodiment of the disclosure can prolong a service life of an OLED display device.

To achieve the above objective, the embodiments of the disclosure employ technical solutions as follows.

In one aspect, an organic light-emitting diode display panel is provided, and the display panel comprises a plurality of pixel units, each pixel unit including at least sub-pixels of three primary colors of red, green and blue made of different organic electroluminescent materials, the pixel unit includes at least three regions, the number of the regions being equal to the number of sub-pixels in the pixel unit, and each of the regions having a same area; the blue sub-pixel is located in at least two regions, and the other sub-pixels of different primary colors are located in different regions, an area of the blue sub-pixel being greater than those of other sub-pixels of a same primary color.

In another aspect, a display device is provided, and the display device comprises the above display panel.

The embodiments of the disclosure provide an organic light-emitting diode display panel and a display device, the organic light-emitting diode display panel can increase an area of a blue sub-pixel by changing an arrangement mode of a pixel unit, thereby reducing current required for emitting light having a same brightness from the blue sub-pixel, and prolonging a service life of the material of a light-emitting layer corresponding to the blue sub-pixel, so that gaps among service lives of the blue sub-pixel, the red sub-pixel and the green sub-pixel are reduced, thus prolonging a service life of the pixel unit, finally prolonging a service life of an OLED display device. Because each region has a same area, an area of the blue sub-pixel is greater than those of the other sub-pixels, and the blue sub-pixel is located in at least two regions, that is, the blue sub-pixel can be extended into a region of the other sub-pixels having smaller area; in this way, in a case where the area of the pixel unit is constant, an aperture ratio of the pixel unit can be maximized.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is an arrangement mode of pixel units of an OLED display device provided in the state of art;

FIG. 2 is an arrangement mode of pixel units of an OLED display device provided by an embodiment of the disclosure; and

FIG. 3 is an arrangement mode of pixel units of another OLED display device provided by an embodiment of the disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments of the disclosure, those ordinarily skilled in the art can obtain other embodiment(s), without any inventive work, which should be within the protective scope of the disclosure.

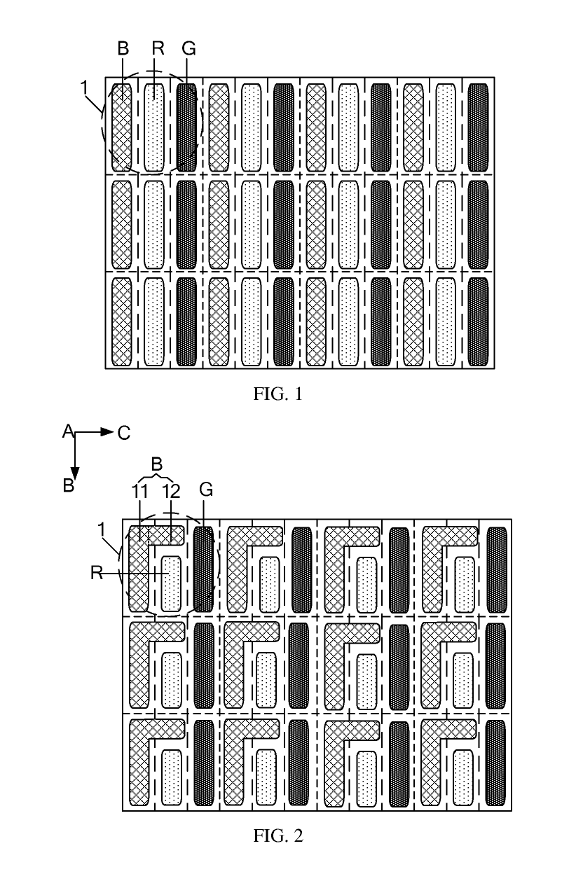

As shown in FIG. 1, an existing OLED display device comprises a plurality of pixel units 1 which can display different colors. Each pixel unit 1 includes a red (R) sub-pixel, a green (G) sub-pixel, and a blue (B) sub-pixel which are arranged side by side, and the three sub-pixels R, G and B are made of organic electroluminescent materials emitting red light, green light and blue light respectively. A principle of the OLED display device to realize color display is that: if the amounts of currents passing through the organic electroluminescent materials are different, intensities of light emitted by the organic electroluminescent materials are different as well. Therefore, the three sub-pixels R, G and B may emit light of different intensities by controlling the amounts of currents passing through the three sub-pixels R, G and B. Since each pixel unit is very small, light emitted by the three sub-pixels R, G and B are mixed into a color to be displayed in each pixel unit visually.

But because of limitation in development of organic electroluminescent materials, at present, the organic electroluminescent materials for emitting blue light have performance and service life far below those of the organic electroluminescent materials for emitting red light and green light. Due to poor performance of a light-emitting layer material corresponding to the sub-pixel B, it is necessary to apply a relatively large current for achieving a desired intensity of light for display. The light-emitting life of the light-emitting layer material is related to amount of current passing therethrough; the greater the current is, the shorter the light-emitting life of the light-emitting layer material is. If the three sub-pixels R, G and B are still arranged in the mode described above, when the service life of the light-emitting layer material corresponding to the sub-pixel B comes to an end, i.e., the sub-pixel B no longer emits light, the display of full color cannot be realized only by the two sub-pixels R and G, thereby reducing the service life of the OLED display device.

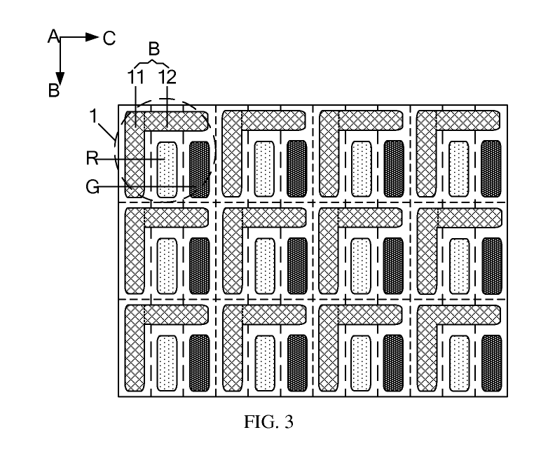

An embodiment of the disclosure provides an organic light-emitting diode display panel; as shown in FIGS. 2 to 3, the display panel comprises a plurality of pixel units 1, and each pixel unit 1 includes at least sub-pixels of three primary colors of red, green and blue that are made of different organic electroluminescent materials. The pixel unit 1 includes at least three regions, the number of the regions being equal to the number of the sub-pixels in the pixel unit, and each of the regions having a same area; the blue sub-pixel is located in at least two regions, and the other sub-pixels of different primary colors are located in different regions, an area of the blue sub-pixel being greater than those of the other sub-pixels of a single primary color.

According to the embodiment of the disclosure, the area of the sub-pixel refers to an area of the light-emitting layer of the sub-pixel, which can emit light. For example, the area is an area measured in an in-plane direction of the display panel.

In the organic light emitting diode display panel described above, the pixel unit includes at least three sub-pixels of three primary colors of red, green and blue made of different organic electroluminescent materials. It can be known from a principle of three primary colors that other colors may be obtained by adjusting the proportion among the three colors of red, green and blue, so the pixel unit should include at least sub-pixels of the three primary colors of red, green, and blue, but the embodiment of the disclosure is not limited thereto; the pixel unit may further include a white sub-pixel, a yellow sub-pixel or the like, and here it is only described in detail by taking an example that the pixel unit includes sub-pixels of the three primary colors of red, green and blue.

In the organic light-emitting diode display panel described above, the pixel unit includes at least three regions, the number of the regions is equal to the number of the sub-pixels in the pixel unit, and each of the regions has a same area. That is, the number of the regions divided in the pixel unit is determined according to the number of the sub-pixels included in the pixel unit. It should be noted that, the sub-pixels of a same primary color included in the pixel unit may be in contact with each other, or not in contact with each other. If the sub-pixels of the same primary color are in contact with each other, the number of the sub-pixels of the primary color is one; if the sub-pixels of the same primary color are not in contact with each other, the number of the sub-pixels of the primary color is a sum of the number of all the sub-pixels of the primary color not in contact with each other, for example, if the pixel unit includes two red sub-pixels which are not in contact with each other, the number of the red sub-pixels in the pixel unit is two.

Exemplarily, if the pixel unit includes sub-pixels of three primary colors of red, green and blue, and the sub-pixels of each primary color are in contact with each other, the pixel unit includes three regions of equal area; if the pixel unit includes sub-pixels of two primary colors of red and green, and the sub-pixels of each primary color are in contact with each other, and the pixel unit further includes three blue sub-pixels which are not in contact with each other, the number of the sub-pixels included in the pixel unit is five, so the pixel unit includes five regions of equal area.

In practice, in order to reduce difficulty in fabricating the sub-pixels, the sub-pixels are usually in contact with each other. The embodiments and drawings of the disclosure all take an example that the sub-pixels of a same primary color are in contact with each other for detailed description, but the arrangement of the sub-pixels is not particularly limited by the disclosure.

In the organic light-emitting diode display panel described above, the blue sub-pixel is located in at least two regions, and the other sub-pixels of different primary colors are located in different regions, an area of the blue sub-pixel being greater than those of the other sub-pixels of a single primary color. Exemplarily, if the pixel unit includes a region a, a region b and a region c, which have a same area, the red sub-pixel and the green sub-pixel may be located in the region a and the region b, respectively, and the blue sub-pixel being located in at least two regions specifically refers to that: a part of the blue sub-pixel may be located in the region c, and the other part of the blue sub-pixel may be located in the region a, or the other part of the blue sub-pixel may be located in the region b, or the other part of the blue sub-pixel may be located in both the region a and the region b, which is not limited in the disclosure, as long as the area of the blue sub-pixel is greater than those of the other kinds of sub-pixels; and the number of the regions where the blue sub-pixel is arranged may be determined according to actual situation.

Because regions are equal in area, an area of the blue sub-pixel is greater than those of the other sub-pixels, and the blue sub-pixel is located in at least two regions, that is, the blue sub-pixel can extend into regions of the other sub-pixels having smaller areas, in this way, in a case where the area of the pixel unit is constant, the aperture ratio of the pixel unit can be maximized. The aperture ratio of a pixel refers to a ratio between a sum of areas of the respective sub-pixels in the pixel unit and the total area of the pixel unit.

For example, the pixel unit is rectangular and an area thereof is 3m*n, the pixel unit includes sub-pixels of three primary colors of red, green and blue, and an area of the blue sub-pixel is greater than those of the red sub-pixel and the green sub-pixel; and the pixel unit includes three regions of a first region, a second region and a third region, whose areas are m*n, respectively. The red sub-pixel is located in the first region, the green sub-pixel is located in the second region, and the blue sub-pixel is located in the first region, the second region and the third region; since the areas of the red sub-pixel and the green sub-pixel are relatively small, the parts in the first region and the second region, which parts are not covered by the red sub-pixel and the green sub-pixel, are covered by the blue sub-pixel, i.e., the blue sub-pixel effectively makes use of the first region and the second region, a sum of the areas of the red sub-pixel, the green sub-pixel and the blue sub-pixel may be extremely close to the total area of the pixel unit, which is favorable to improve the aperture ratio of the pixel unit.

It should be noted that, the shape, size, sequence of each sub-pixel in the pixel unit is not limited here, as long as the above requirements are met.

An embodiment of the disclosure provides an organic light-emitting diode display panel; the organic light-emitting diode display panel increases an area of the blue sub-pixel by changing an arrangement mode of the pixel unit, so that the required current is smaller while light of a same intensity is emitted by the blue sub-pixel, and a light-emitting life of a light-emitting layer material corresponding to the blue sub-pixel is prolonged, thereby reducing gaps among the light-emitting lives of the blue sub-pixel, the red sub-pixel, and the green sub-pixel, prolonging the light-emitting life of the pixel unit, and finally prolonging the service life of the OLED display device.

Optionally, because the organic electroluminescent material for forming a blue sub-pixel has performance and service life far below those of the organic electroluminescent material for emitting red light, part of the blue sub-pixel and the red sub-pixel may be located in a same region, that is, the blue sub-pixel are located in two regions, the red sub-pixel is located in one of the two regions, so as to further reduce a gap between the light-emitting lives of the blue sub-pixel and the red sub-pixel, finally prolonging the service life of the OLED display device.

Optionally, the blue sub-pixel is located in three regions, the red sub-pixel and the green sub-pixel are located in one of the three regions, respectively; in this way, a part of the blue sub-pixel is located in one region, a second part of the blue sub-pixel and the red sub-pixel are located in a same region, the rest part of the blue sub-pixel and the green sub-pixel are located in a same region; and therefore, when the organic electroluminescent material for forming the red sub-pixel has almost same performance and life as the organic electroluminescent material for forming the green sub-pixel, such a pixel arrangement mode is more favorable to balance light-emitting lives of the sub-pixels of the three colors of red, green and blue, to maximize the light-emitting life of the pixel unit.

Further, as shown in FIGS. 2 to 3, the blue sub-pixel includes a first portion 11 and a second portion 12 intersecting with each other; the first portion 11 is located in one region, and a part of the second portion 12 and the sub-pixels of other colors are located in same regions. It should be noted that, the existing display panel comprises gate lines and data lines, and in the embodiments of the disclosure, a first direction may be an arrangement direction of the gate lines, and a second direction may be an arrangement direction of the data lines; or, a first direction may be an arrangement direction of the data lines, and a second direction may be an arrangement direction of the gate lines.

Furthermore, as shown in FIGS. 2 to 3, a first portion 11 of the blue sub-pixel is parallel to the first direction, i.e., an AB direction, a second portion 12 is parallel to the second direction, i.e., an AC direction; the first direction, i.e., the AB direction, is perpendicular to the second direction, i.e., the AC direction; the AB direction is perpendicular to the AC direction, so as to reduce difficulty in fabricating the blue sub-pixel.

It should be noted that, specific orientations of the first and second directions are not limited here, as long as it is satisfied that the first direction is perpendicular to the second direction. Specifically, for example, the display panel further comprises a plurality of gate lines and a plurality of data lines, the first direction may be a direction along the gate lines of the display panel, and the second direction may be a direction perpendicular to the gate lines of the display panel; or, the first direction may also be a direction along the data lines of the display panel, and the second direction may be a direction perpendicular to the data lines of the display panel. The embodiment and drawings of the disclosure are described by only taking an example that the first direction is an AB direction, and the second direction is an AC direction, wherein the AB direction is perpendicular to the AC direction.

Further optionally, as shown in FIGS. 2 to 3, a maximum width of the first portion 11 of the blue sub-pixel along the second direction, i.e., the AC direction, is same as those of the other sub-pixels along the second direction, i.e., the AC direction, and a maximum width of the second portion 12 along the first direction, i.e., the AB direction, is the same as that of the first portion along the second direction, i.e., the AC direction, so as to further reduce difficulty in fabricating the sub-pixels of different colors.

Further optionally, as shown in FIG. 2, an area of the green sub-pixel is greater than that of the red sub-pixel, so that when the organic electroluminescent material for forming the red sub-pixel has better performance and longer life than those of the organic electroluminescent material for forming the green sub-pixel, light-emitting lives of the sub-pixels of the two colors of red and green may be further balanced, thereby further prolonging the light-emitting life of the pixel unit

Optionally, in order to further increase the brightness of the display panel to improve a display effect, the pixel unit may further include a white sub-pixel or a yellow sub-pixel, and an area of the yellow sub-pixel or the white sub-pixel is less than that of the red sub-pixel.

An organic light-emitting diode display panel is provided according to some other embodiments of the disclosure; the display panel comprises a plurality of pixel units, and each pixel unit at least includes sub-pixels of three primary colors of red, green and blue made of different organic electroluminescent materials. An area of the blue sub-pixel is greater than those of the red sub-pixel and the green sub-pixel.

In some examples, an area of the green sub-pixel is greater than that of the red sub-pixel.

In some examples, the pixel unit further includes a white sub-pixel or a yellow sub-pixel, and an area of the white sub-pixel or the yellow sub-pixel is less than that of the red sub-pixel.

An embodiment of the disclosure provides a display device, and the display device comprises the organic light-emitting diode display panel described above, which has characteristics such as good performance, longer service life and so on. The display device can be a display device such as an OLED display, or any product or component having a display function, such as a TV, a digital camera, a mobile telephone, or a tablet PC including the display device.

The foregoing embodiments merely are exemplary embodiments of the present disclosure, and not intended to define the scope of the present disclosure, and the scope of the disclosure is determined by the appended claims.

The present application claims priority of Chinese Patent Application No. 201410832109.1 filed on Dec. 26, 2014, the disclosure of which is incorporated herein by reference in its entirety as part of the present application.

1. An organic light-emitting diode display panel, comprising a plurality of pixel units, each pixel unit including at least sub-pixels of three primary colors of red, green and blue made of different organic electroluminescent materials, wherein,
the pixel unit includes at least three regions, a number of the regions being equal to a number of sub-pixels in the pixel unit, and each of the regions having a same area;
the blue sub-pixel is located in at least two regions, and the other sub-pixels of different primary colors are located in different regions, an area of the blue sub-pixel being greater than those of other sub-pixels of a same primary color.

2. The display panel according to claim 1, wherein, the blue sub-pixel includes a first portion and a second portion intersecting with each other; the first portion is located in a region, and at least part of the second portion and the sub-pixels of other colors are located in a same region.

3. The display panel according to claim 2, wherein, the first portion is a stripe-shaped structure extending along a first direction, and the second portion is a stripe-shaped structure extending along a second direction, the first direction being perpendicular to the second direction.

4. The display panel according to claim 3, wherein, a maximum width of the first portion along the second direction is same as those of other sub-pixels along the second direction.

5. The display panel according to claim 3, a maximum width of the second portion along the first direction is same as that of the first portion along the second direction.

6. The display panel according to claim 1, wherein, the blue sub-pixel is located in two regions, and the red sub-pixel is located in one of the two regions.

7. The display panel according to claim 2, wherein, the blue sub-pixel is located in two regions; and the red sub-pixel and a first portion of the blue sub-pixel are located in different regions, and the red sub-pixel and a second portion of the blue sub-pixel are located in a same region.

8. The display panel according to claim 1, wherein, the blue sub-pixel is located in three regions, and the red sub-pixel and the green sub-pixel are located in one of the three regions.

9. The display panel according to claim 2, wherein, the blue sub-pixel is located in three regions; and the red sub-pixel and a first portion of the blue sub-pixel are located in different regions, and the red sub-pixel and a second portion of the blue sub-pixel are located in a same region.

10. The display panel according to claim 1, wherein, an area of the green sub-pixel is greater than that of the red sub-pixel.

11. The display panel according to claim 1, wherein, the pixel unit further includes a white sub-pixel or a yellow sub-pixel, and an area of the white sub-pixel or the yellow sub-pixel is less than that of the red sub-pixel.

12. A display device, comprising the display panel according to claim 1.

13. An organic light-emitting diode display panel, comprising a plurality of pixel units, each pixel unit including at least sub-pixels of three primary colors of red, green and blue made of different organic electroluminescent materials, wherein,
an area of the blue sub-pixel is greater than those of the red sub-pixel and the green sub-pixel.

14. The display panel according to claim 13, wherein, an area of the green sub-pixel is greater than that of the red sub-pixel.

15. The display panel according to claim 13, wherein, the pixel unit further includes a white sub-pixel or a yellow sub-pixel, and an area of the white sub-pixel or the yellow sub-pixel is less than that of the red sub-pixel.

16. The display panel according to claim 4, a maximum width of the second portion along the first direction is same as that of the first portion along the second direction.

17. The display panel according to claim 2, wherein, an area of the green sub-pixel is greater than that of the red sub-pixel.

18. The display panel according to claim 2, wherein, the pixel unit further includes a white sub-pixel or a yellow sub-pixel, and an area of the white sub-pixel or the yellow sub-pixel is less than that of the red sub-pixel.

19. The display panel according to claim 6, wherein, an area of the green sub-pixel is greater than that of the red sub-pixel.

20. The display panel according to claim 6, wherein, the pixel unit further includes a white sub-pixel or a yellow sub-pixel, and an area of the white sub-pixel or the yellow sub-pixel is less than that of the red sub-pixel.
